(19) United States
(12) Patent Application Publication
(10) Pub. No.: US 2007/0086167 A1
(43) Pub. Date: Apr. 19, 2007

(54) Heat sink having speed-up heat-dissipating structure

(75) Inventor: Jung-Shun Chen, Jen Te Hsiang (TW)

Correspondence Address: ELIZABETH CHIEN-HALE, 40087 MISSION BLVD. BOX 367, FREMONT, CA, 94539, US

(73) Assignee: Chi Lin Technology Co., Ltd.

(21) Appl. No.: 11/253,489

(22) Filed: Oct. 18, 2005

(51) Int. Cl. H05K 7/20

(52) U.S. Cl. 361/710

(57) ABSTRACT

A heat sink having speed-up heat-dissipating structure is provided. The heat sink includes a first and second heat-dissipating surface, wherein a plurality of heat-dissipating strips is formed in annular shape on the first heat-dissipating surface without intersecting each other, and the cross-sectional areas of the heat-dissipating strips and the space between them increase from the center area to the periphery of the first heat-dissipating surface. The plurality of heat-dissipating strips is spread around a circle with its center coincided with or near the center of the first heat-dissipating surface. Moreover, a board is laminated on the first heat-dissipating surface of the heat sink, and a fan is disposed on the board. When the heat sink is used in a backlight module, the heat sink makes the high-temperature air flow rate relatively high after the heat exchange is completed to achieve optimum heat-exchange effect.

### BACKGROUND OF THE INVENTION

1. Field of the Invention

The invention relates to a heat sink, and more particularly, to a heat sink having speed-up heat-dissipating structure whose design has good heat-dissipating flow channel to improve the speed-up heat-dissipating efficiency, and when it comes to being employed in liquid crystal display (LCD), the heat-dissipating structure can effectively reduce the thickness of the LCD.

2. Description of the Prior Art

The rapid and vigorous growth of the information technology nowadays makes it very convenient for one to obtain information. This is due to the fast production of electronic information products of high technology. Consequently, the working efficiency of the electronic information products is constantly improving and the working speed of their inner electronic devices is ever increasing. Nevertheless, many accompanied heat-dissipating problems at high temperature caused by the high speed working speed of the electronic devices are apt to shorten their service life, and in more serious situation, it may even damage the electronic information products to make them in faulted condition. Therefore, one must be rigorous on the demand of the design for the heat sink inside the information products by making use of the limited space to achieve optimum heat-dissipating efficiency.

Generally speaking, the metal materials used for the heat sink are nothing more than gold, silver, copper, aluminum etc. These metals are essential factors on affecting the design of heat sink. However, under the status that the metal materials used for heat sink do not have any revolutionary development, the heat sink of today considers to employ some other factors to improve its heat-dissipating design. For examples, factors such as to enlarge the size of the heat sink or redesign the configuration of the heat sink are considered to employ. However, since the design of electronic information products of today requires ones that are “light, thin, short, and small”, enlarging the size of the heat sink to improve the rate of heat dissipation does not meet the requirements for the electronic information products. Besides, for the redesign of the configuration of the heat sink, although there are many novel configurative designs of heat sink on the market, their modes of heat-dissipating design of the conventional heat sink have not been sufficient to meet the heat-dissipating efficiency requirements of the electronic information products of today. FIG. 1 is a schematic diagram of the heat sink of the prior art. As shown in FIG. 1, the cooling effect of the heat sink having the strip type heat-dissipating bars is limited since it does not consider the design of the overall heat-dissipating flow channel. The heat-dissipating effect of this kind of heat sink is not sufficient, especially when it comes to being used in the electronic information products having relatively higher speed in heat accumulation. Moreover, the gap between the heat sink and the fan make it requires relatively large space when it comes to have the heat sink use in LCD causing the volumetric thickness become relatively thicker. Once the volumetric thickness become relatively thicker, it will affect the sale competitiveness of the LCD making the manufacturers' profit relatively lower.

Consequently, when it comes to being used in LCD, the heat sink of the prior art will cause the ineffectiveness of the heat dissipation. Therefore, how to redesign a heat sink structure having good heat-dissipating flow channel and being able to improve speed-up heat-dissipating efficiency has become the goal of the manufacturers' research and development.

### SUMMARY OF THE INVENTION

In light of the disadvantages of the prior arts, the invention provides a heat sink having speed-up heat-dissipating structure that aims to ameliorate at least some of the disadvantages of the prior art or to provide a useful alternative.

The objective of the invention is to provide a heat sink having speed-up heat-dissipating structure to resolve the drawback of having ineffectiveness of the heat dissipation of the heat sink structure of the prior art and to overcome the drawback that the volumetric thickness of the LCD become relatively thicker.

To achieve the above-mentioned objectives, the invention provides a heat sink having speed-up heat-dissipating structure. The heat sink includes a first heat-dissipating surface and a second heat-dissipating surface, wherein a plurality of heat-dissipating strips is formed in annular shape on the first heat-dissipating surface without intersecting each other, and the cross-sectional areas of the heat-dissipating strips and the space between them increase from the center area to the periphery of the first heat-dissipating surface. The plurality of heat-dissipating strips is spread around a circle with its center coincided with or near the center of the first heat-dissipating surface. Moreover, a board is laminated on the first heat-dissipating surface of the heat sink, and a fan is disposed on the board. When the heat sink having speed-up heat-dissipating structure is used in a backlight module, since the cross-sectional area of the plurality of heat-dissipating strips (20) is relatively small at the center of the first heat-dissipating surface (11), the high-temperature air flow rate is relatively high after the heat exchange is completed. In addition, the heat sink of the invention can achieve optimum heat-exchange effect since the heat after being heat-exchanged is quickly drawn out by the fan.

The accomplishment of this and other objectives of the invention will become apparent from the following description and its accompanying drawings of which:

### BRIEF DESCRIPTION OF THE DRAWINGS

FIG. 1 is a schematic diagram of the heat sink of the prior art;

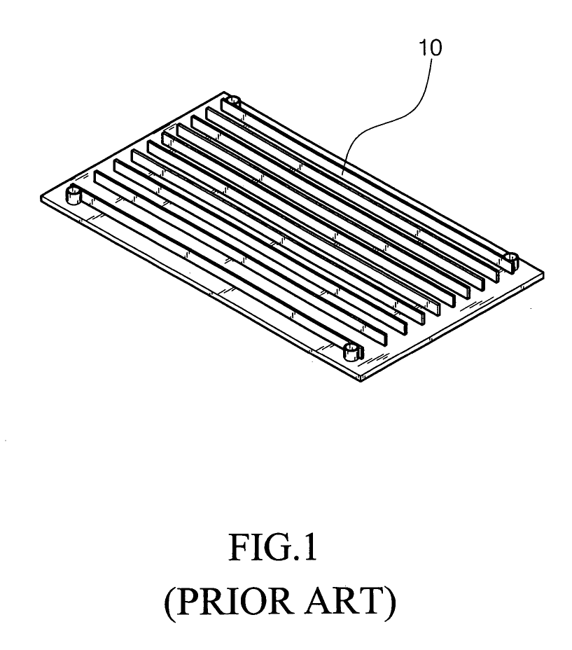

FIG. 2A is an exploded view of the heat sink structure of the invention;

FIG. 2B is an isometric view of the assembled heat sink structure of the invention;

FIG. 3 is an isometric view of a multi-piece assembled heat sink structure of the invention; and

FIG. 4 is an exploded view of the heat sink used in a backlight module of the invention.

### DETAILED DESCRIPTION OF THE PREFERRED EMBODIMENT

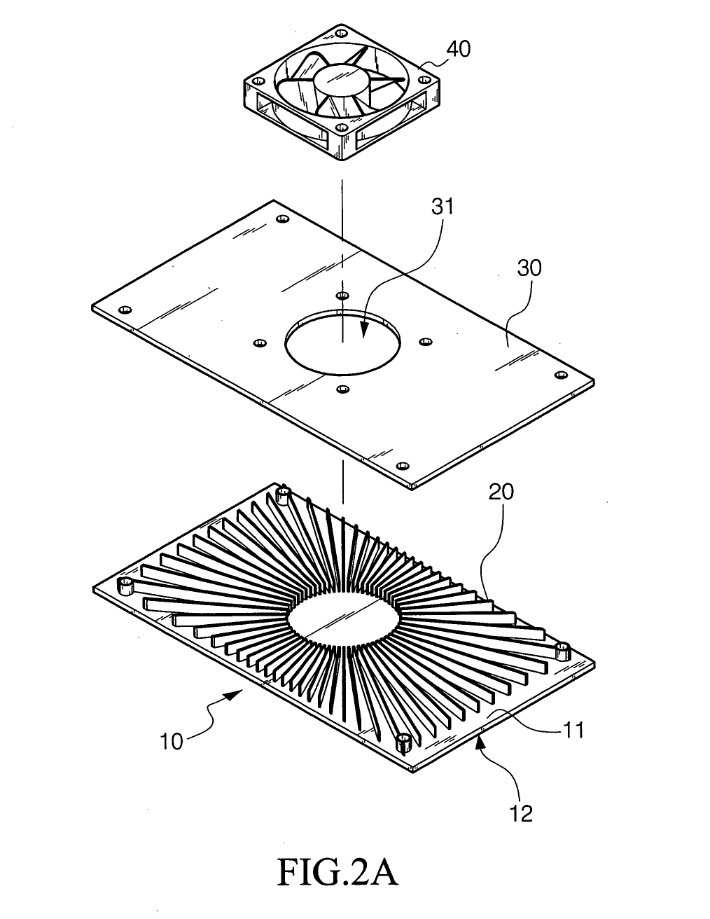

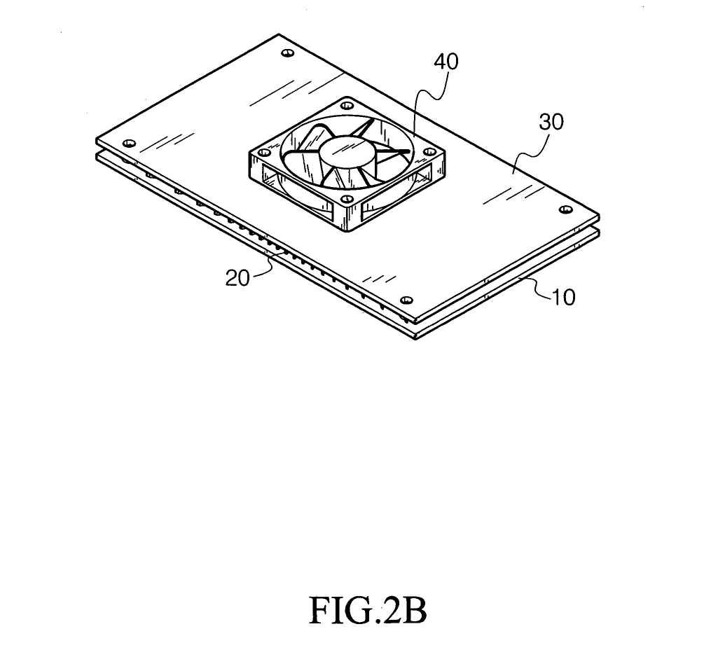

FIG. 2A is an exploded view of the heat sink structure of the invention; and FIG. 2B is an isometric view of the assembled heat sink structure of the invention. As shown in FIG. 2A and FIG. 2B, the invention is related to a heat sink having speed-up heat-dissipating structure. The heat sink (10) includes a plurality of heat-dissipating strips (20) having a board (30) laminated thereon, and a fan (40) disposed on the board (30).

Referring again to FIG. 2A and FIG. 2B, the invention is related to a heat sink having speed-up heat-dissipating structure. The heat sink (10) includes a first heat-dissipating surface (11) and a second heat-dissipating surface (12). A plurality of heat-dissipating strips (20) is formed in radial direction without intersecting each other and are spread around a circle with its center coincided with or near the center of the first heat-dissipating surface (11). The cross-sectional area of the heat-dissipating strip (20) and the space between them increase from the center area to the periphery of the first heat-dissipating surface (11). Moreover, the heat-dissipating strips (20) distribute more densely at the center than those at the periphery of the first heat-dissipating surface (11). Furthermore, a board (30) providing a hole (31) at the center of the first heat-dissipating surface (11) is laminated thereon and a fan (40) is disposed on the top of the hole (31) of the board (30).

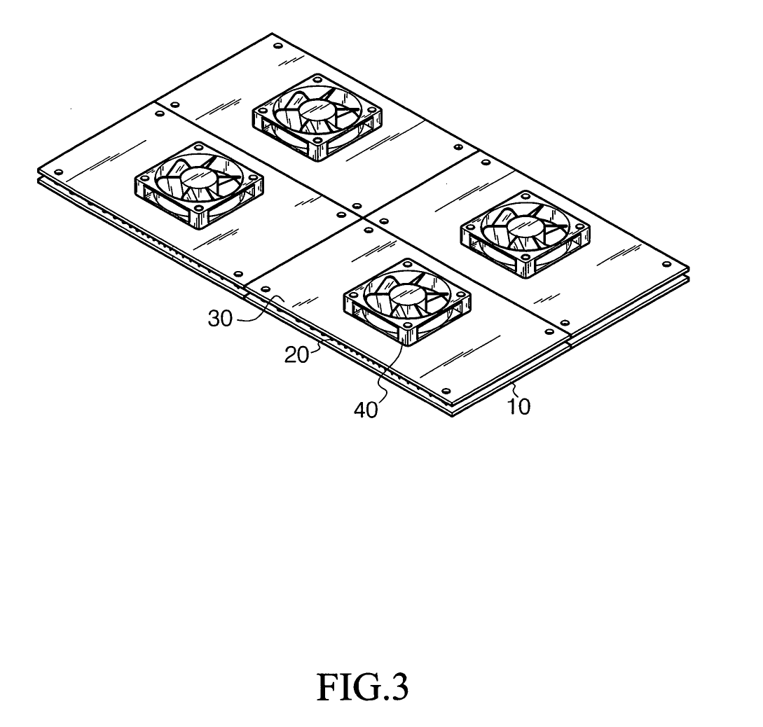

The invention is related to a heat sink having speed-up heat-dissipating structure, and the above-mentioned heat sink (10) is a thin sheet. What is more, the above-mentioned heat sink (10) and board (30) are made of metal. Moreover, to meet different heat-dissipating requirements, the invention can have a multiplication of heat sinks (10) combined, and of course, each of the heat sinks (10) is laminated with a board (30) and disposed on a fan (40) as shown in FIG. 3.

The invention is related to a heat sink having speed-up heat-dissipating structure. The invention provides a heat sink having speed-up heat-dissipating structure to be used in the back plate of the backlight module of an LCD. The features illustrated below are for the preferred embodiment as the heat sink is employed in the backlight module.

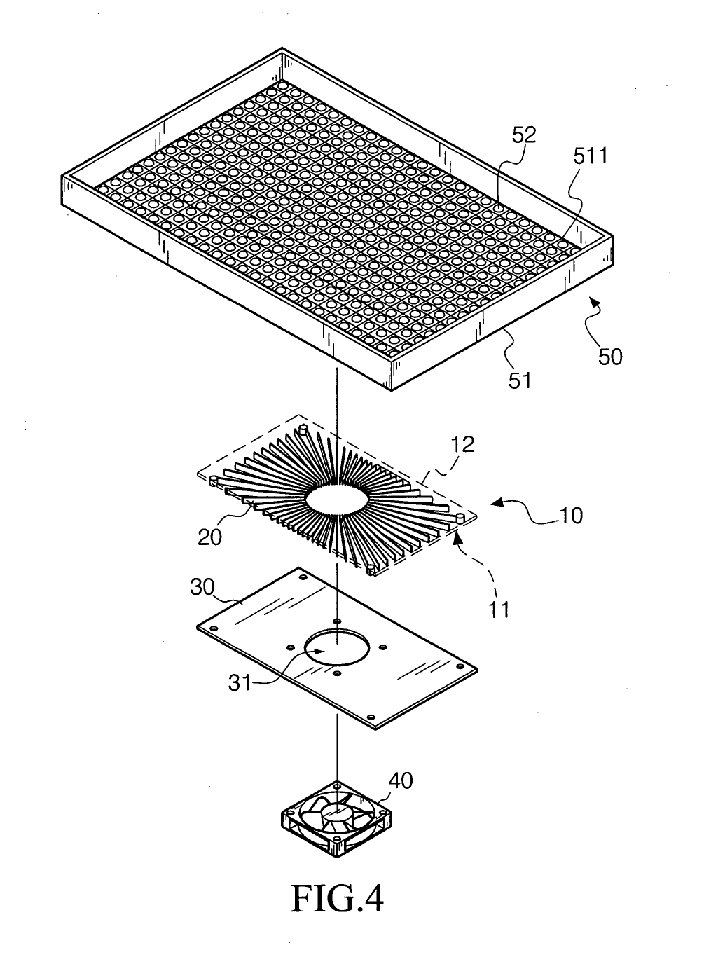

FIG. 4 is an exploded view of the heat sink used in a backlight module of the invention. As shown in FIG. 4, the heat sink having speed-up heat-dissipating structure is used in a backlight module (50). The backlight module (50) includes a backplate (51) and a light source (52) provided on the upper surface (511) of the backplate (51).

Referring again to FIG. 4, when the heat sink having speed-up heat-dissipating structure of the invention is equipped in the backlight module (50), the backplate (51) is first laminated on the second heat-dissipating surface (12) of the heat sink (10). The board (30) is laminated beneath the first heat-dissipating surface (11) with hole (31) aligning with the center of the board (30), and the fan (40) is attached on the top of the hole (31) of the board (30). A plurality of heat-dissipating strips (20) is formed in radial direction without intersecting each other and are spread around a circle with its center coincided with or near the center of the first heat-dissipating surface (11). Moreover, the cross-sectional area of the heat-dissipating strip (20) and the space between them increase from the center area to the periphery of the first heat-dissipating surface (11). What is more, the heat-dissipating strips (20) distribute more densely at the center than those at the periphery of the first heat-dissipating surface (11). For these reasons, while the heat generated by the light source (52) of the backlight module (50) is transferred through the plurality of heat-dissipating strips (20) of the heat sink (10), since the cross-sectional area of the plurality of heat-dissipating strips (20) is relatively small at the center of the first heat-dissipating surface (11), the high-temperature air flow rate is relatively high after the heat exchange is completed. In addition, since the heat after being heat-exchanged is quickly drawn out by the use of the fan (40), the heat-exchanged surface of the plurality of heat-dissipating strips (20) of the heat sink (10) can maintain at constant temperature to achieve optimum heat-exchanged efficiency.

When the heat sink having speed-up heat-dissipating structure of the invention is used in a backlight module (50), the backplate (51) of the backlight module (50) can further include a reflecting layer and a diffusion plate (not shown in the Figure) to improve the light availability of the light source (52) of the backlight module (50). The reflecting layer of the backlight module (50) is provided on the backplate under the light source (52) as shown in the backlight module of the prior art while the diffusion plate is provided on the backplate above the light source (52).

It will become apparent to those people skilled in the art that various modifications and variations can be made to the structure of the invention without departing from the scope or spirit of the invention. In view of the foregoing description, it is intended that all the modifications and variation fall within the scope of the following appended claims and their equivalents.

What is claimed is:

1. A heat sink having speed-up heat-dissipating structure, comprising a first heat-dissipating surface and a second heat-dissipating surface, wherein a plurality of heat-dissipating strips is formed in annular shape on the first heat-dissipating surface without intersecting each other, and the cross-sectional areas of the heat-dissipating strips and the space between them increase from the center area to the periphery of the first heat-dissipating surface.

2. The heat sink having speed-up heat-dissipating structure as claimed in claim 1, wherein the plurality of heat-dissipating strips is spread around a circle with its center coincided with or near the center of the first heat-dissipating surface.

3. The heat sink having speed-up heat-dissipating structure as claimed in claim 1, wherein the plurality of heat-dissipating strips is formed on the first heat-dissipating surface in radial direction.

4. The heat sink having speed-up heat-dissipating structure as claimed in claim 1, wherein a board is laminated on the first heat-dissipating surface of the heat sink.

5. The heat sink having speed-up heat-dissipating structure as claimed in claim 1, wherein a through hole is provided on the board.

6. The heat sink having speed-up heat-dissipating structure as claimed in claim 1, wherein a fan is disposed above the hole of the board.

7. The heat sink having speed-up heat-dissipating structure as claimed in claim 1, wherein the heat sink is a thin sheet.

8. The heat sink having speed-up heat-dissipating structure as claimed in claim 1, wherein the heat sink is made of metal.

9. The heat sink having speed-up heat-dissipating structure as claimed in claim 4, wherein the board is made of metal.

10. A heat sink having speed-up heat-dissipating structure used in a backlight module comprising a backlight module, a first heat-dissipating surface and a second heat-dissipating surface, wherein the backlight module is laminated on the second heat-dissipating surface of the heat sink, and a plurality of heat-dissipating strips is formed in annular shape on the first heat-dissipating surface without intersecting each other, and the cross-sectional area and space between the heat-dissipating strips increase from the center area to the periphery of the first heat-dissipating surface.

11. The heat sink having speed-up heat-dissipating structure as claimed in claim 10, wherein the plurality of heat-dissipating strips is spread around a circle with its center coincided with or near the center of the first heat-dissipating surface.

12. The heat sink having speed-up heat-dissipating structure as claimed in claim 10, wherein the plurality of heat-dissipating strips is formed on the first heat-dissipating surface in radial direction.

13. The heat sink having speed-up heat-dissipating structure as claimed in claim 10, wherein a board is laminated on the first heat-dissipating surface of the heat sink.

14. The heat sink having speed-up heat-dissipating structure as claimed in claim 10, wherein a through hole is provided on the board.

15. The heat sink having speed-up heat-dissipating structure as claimed in claim 10, wherein a fan is disposed above the hole of the board.

16. The heat sink having speed-up heat-dissipating structure as claimed in claim 10, wherein the heat sink is a thin sheet.

17. The heat sink having speed-up heat-dissipating structure as claimed in claim 10, wherein the heat sink is made of metal.

18. The heat sink having speed-up heat-dissipating structure as claimed in claim 13, wherein the board is made of metal.
